(19) United States
(12) Patent Application Publication
(10) Pub. No.: US 2008/0291746 A1
(43) Pub. Date: Nov. 27, 2008

(54) Semiconductor Storage Device and Burst Operation Method

(76) Inventors: Toshio Sunaga, Shiga-ken (JP); Kohji Hosokawa, Shiga-ken (JP); Hisatada Miyatake, Shiga-ken (JP); Yutaka Nakamura, Kyoto-fu (JP)

Correspondence Address: IBM MICROELECTRONICS;INTELLECTUAL PROPERTY LAW, 1000 RIVER STREET, 972 E, ESSEX JUNCTION, VT, 05452, US

(21) Appl. No.: 10/595,742

(22) PCT Filed: Nov. 4, 2004
(86) PCT No.: PCT/JP04/16296

§ 371 Date: May 8, 2006

(30) Foreign Application Priority Data
Nov. 6, 2003 (JP) 2003-377485

(51) Int. Cl. G11C 7/00; G11C 8/00

(52) U.S. Cl. 365/189.05; 365/230.03; 365/205; 365/230.06; 365/233.1

(57) ABSTRACT

The present invention is a PSRAM in which a burst length can be increased without increasing consumed current, and a burst operation method therefor. In operation, column selection lines CSL1 and CSL2 are driven in order during activation of sense amplifiers. This causes bit switches BSW1-BSW8 to be turned on in units of four bit switches and then 8-bit read data RD is latched from bit line pairs BL1-BL8 into prefetch/preload latches PFPLL1-PFPLL8 in units of 4-bits. The 8-bit read data RD is continuously output to a single data I/O bus I/O1 in units of one bit and in order.

### CROSS REFERENCE TO RELATED APPLICATIONS

This application is based on PCT application No. PCT/JP2004/16296, filed Nov. 4, 2004 which claims priority to Japanese Patent Application 2003-377485, filed Nov. 6, 2003, now abandoned, herein incorporated by reference.

### BACKGROUND OF THE INVENTION

1. Field of the Invention

The present invention relates to a semiconductor memory and a burst operation method therefor, and more particularly to an improvement of a dynamic random accesses memory (DRAM) capable of inserting a refresh operation during a normal access operation and a burst operation method therefor.

2. Background of the Invention

In recent years, it has become popular to replace a static random accesses memory (SRAM) with a DRAM for uses in low power consumption. It is because a storage capacity per unit area of the DRAM is much larger than that of the SRAM. The DRAM, however, needs a refresh, which is unnecessary for the SRAM. Therefore, what is needed is a pseudo SRAM (hereinafter, referred to as “PSRAM (pseudo static random accesses memory),” which can be used in quite the same way as in the SRAM for a user through an automatic refresh performed by an internal circuit of the DRAM, instead of a refresh performed by an external circuit such as a refresh controller.

### BRIEF SUMMARY OF THE INVENTION

It is an object of the present invention to provide a semiconductor memory in which a burst length can be increased without increasing consumed current and a burst operation method therefor.

The invention described below discloses a PSRAM and a method of inserting a normal access operation and a refresh operation into a single external cycle time. According to this method, an internal cycle time for the access and an internal cycle time for the refresh are secured in the single external cycle time, thus enabling a refresh to be performed at any time without putting off the normal access.

For the PSRAM, the external cycle time is a practical cycle time that determines an operation speed. Therefore, to accelerate the PSRAM, the external cycle time needs to be reduced. For this purpose, however, the internal cycle time needs to be reduced to less than one half of the external cycle time and thus the reduction of the external cycle time is not an easy matter. The PSRAM has originally been provided with an internal cycle time for a refresh secured in each external cycle time so that the refresh can be performed at any time. Therefore, it can show only half of its performance and it is hard to achieve the acceleration.

To resolve the disadvantage, PSRAMs which adopt a page mode or a burst mode are presented.

FIG. 13 illustrates a PSRAM adopting an 8-bit burst mode with an 8-bit prefetch. Referring to FIG. 13, the PSRAM 1 comprises a memory cell array 2 including memory cells MC of 64M (=64×10²⁰), word lines WL of 8K (=8×2¹⁰), and bit line pairs BL of 8K.

The PSRAM 1 further comprises row decoders 3 for selectively driving a word line WL, a column decoder 4, for selecting a bit line pair BL by selectively driving a column selection line (not shown), 16 data I/O buses 5, and a data path circuit 6 for exchanging read or write data between the memory cell arrays 2 and the I/O buses 5.

The data path circuit 6 includes 128 secondary sense amplifiers (read buffers) (not shown), 128 write buffers (not shown), and 128 prefetch/preload latches (not shown). Each secondary sense amplifier supplies read data from the memory cell array 2 to a corresponding prefetch/preload latch. Each write buffer supplies write data received from the data I/O bus 5 to a corresponding prefetch/preload latch. The prefetch/preload latch retains the read or write data temporarily.

As shown in FIG. 14, data is read out to bit line pairs BL upon a drive of word lines WL and the data is amplified upon activation of the sense amplifiers. When column selection lines CSL are driven in this mode, bit switches (not shown) are turned on. The data is then read out from the bit line pairs via the bit switches. The read data is amplified by the secondary sense amplifiers and latched to the prefetch/preload latches.

In a full bit prefetch mode in which data of the entire burst length is latched, 8-bit data is read or written at each input or output and therefore 128-bit (=8 bits×16) data is read or written in total. In other words, a single word line WL is selected; all of the 8K sense amplifiers SA are activated; and 128-bit read data is fetched from the 8K-bit read data to 128 prefetch/preload latches, respectively. Thereafter, 128-bit read data is distributed to 16 data I/O buses 5 and 8-bit read data for each input or output is output continuously.

Referring to FIG. 15, there is shown a PSRAM adopting a 16-bit burst mode with a 16-bit prefetch. A data path circuit 8 of the PSRAM 7 includes 256 secondary sense amplifiers, 256 write buffers, and 256 prefetch/preload latches, whose amounts are twice those of the above.

In this case, 16-bit data is read or written at each input or output, and therefore 256-bit (=16 bits×16) data is read or written in total. In other words, two word lines WL in arrays different from each other are selected at a time; 16K sense amplifiers SA1 and SA2, whose amount is twice that of the above, are activated; and 256-bit read data is fetched from the 16K-bit read data to 256 prefetch/preload latches, respectively. Thereafter, 256-bit read data is distributed to 16 data I/O buses 5 and 16-bit read data for each input or output is output continuously.

The twofold burst length thus doubles the number of activated sense amplifiers and the number of charged or discharged bit line pairs, thereby also doubling the current flowing within the memory cell array 2.

While the burst mode is a publicly known operation adopted in an SDRAM, a mode referred to as a wrap mode is adopted in general.

In the wrap mode, a column access is repeated only within an 8- or 16-bit burst area or the like. More specifically, unless the first column address corresponds to a head of the burst area, the column access starts in the middle of the burst area and a return is made to the head of the same burst area at the end of the burst area. This causes the 8- or 16-bit data to be read out continuously.

The present PSRAM, however, is required to operate in a non-wrap mode. In the non-wrap mode, when the column access is made up to the end of the burst area, it is continued with a progress to a head of the next burst area, instead of returning to the head of the same burst area.

Even in the 8-bit burst non-wrap mode with the 8-bit prefetch shown in FIG. 13, 8-bit read data RD1-RD8 are continuously output with a repetition of a row access as shown in FIG. 16(a) if the column access starts at a head of the 8-bit burst area. In this case, the 8-bit read data RD1-RD8 are transferred in order from the prefetch/preload latches to the data I/O bus 5 and a fetch of the next 8-bit read data RD1-RD8 is completed before an end of a transfer of the last read data RD8. Thereby, the read data RD is output without a gap on the data I/O bus 5.

No gap is left if the column access starts at the 6^{th} bit (the third to last bit) of the 8-bit burst area. It is because the fetch operation of the next 8-bit read data RD1-RD8 is completed during a transfer of read data RD6-RD8 of three bits or the 6^{th}-8^{th} bits.

If, however, the column access starts at the 7^{th} bit (the last bit but one) of the 8-bit burst area as shown in FIG. 16(b), a 5-ns gap is left.

It is because a fetch of the next 8-bit read data RD1-RD8 is not completed during a transfer of read data RD7 and RD8 of two bits or the 7th and 8th bits. Similarly, if the column access starts at the 8th bit (the last bit) of the 8-bit burst area, a longer 20-ns gap is left.

Even in the 16-bit burst non-wrap mode with the 16-bit prefetch shown in FIG. 15, 16-bit read data RD1-RD16 are continuously output with a, repetition of a row access as shown in FIG. 17(a) if the column access starts at a head of the 16-bit burst area. In this case, the 16-bit read data RD1-RD16 are transferred in order from the prefetch/preload latches to the data I/O bus 5 and a fetch of the next 16-bit read data RD1-RD16 is completed before an end of a transfer of the last read data RD16. Thereby, the read data RD is output without a gap on the data I/O bus 5.

If, however, the column access starts at the 15^{th} bit (the next to last bit) of the 16-bit burst area as shown in FIG. 17(b), a 5-ns gap is left.

It is because a fetch of the next 16-bit read data RD1-RD16 is not completed during a transfer of read data RD15 and RD16 of two bits or the 15th and 16th bits. Similarly, if the column access starts at the 16th bit (the last bit) of the 16-bit burst area, a longer 20-ns gap is left.

As mentioned above, the conventional full bit prefetch mode has such a problem that current flowing in the memory cell array increases as a burst length or a page length increases.

Furthermore, the non-wrap burst mode has such a problem that a gap is made if a column access starts at the last or the next-to-last column of the burst area and thus continuous burst read data cannot be achieved.

### BRIEF DESCRIPTION OF THE DRAWINGS

FIG. 1 is a functional block diagram showing a configuration of a PSRAM according to an embodiment of the present invention;

FIG. 2 is a functional block diagram showing a configuration of one half of a data path circuit corresponding to a single array block shown in FIG. 1;

FIG. 3 is a functional block diagram showing details of a part of the memory cell array and the data path circuit shown in FIG. 1 and FIG. 2, respectively;

FIG. 4 is a functional block diagram showing a column decoder shown in FIG. 1 and its peripheral circuits;

FIG. 5 is a timing chart showing an operation of the column decoder and its peripheral circuits shown in FIG. 6;

FIG. 6 is a timing chart showing an operation of the PSRAM shown in FIG. 1 to FIG. 5;

FIG. 7 is a timing chart showing an 8-bit burst operation with two shots and a 4-bit prefetch of the PSRAM shown in FIG. 1 to FIG. 5;

FIG. 8 is a timing chart showing another example of an operation different from that in FIG. 6;

FIG. 9 is a timing chart showing a 16-bit burst operation with two shots, a 4-bit prefetch, and two row accesses of the PSRAM shown in FIG. 1 to FIG. 5;

FIG. 10 is a timing chart showing a 4-shot operation different from the operation in FIG. 6;

FIG. 11 is a timing chart showing another example of an operation;

FIG. 12 is a timing chart showing a 16-bit burst operation with four shots and a 4-bit prefetch of the PSRAM shown in FIG. 1 to FIG. 5;

FIG. 13 is a functional block diagram showing a configuration of a conventional PSRAM adopting an 8-bit burst mode with an 8-bit prefetch;

FIG. 14 is a timing chart showing an operation of the PSRAM shown in FIG. 13;

FIG. 15 is a functional block diagram showing a configuration of a conventional PSRAM adopting a 16-bit burst mode with a 16-bit prefetch;

FIG. 16 is a timing chart showing a non-wrap burst operation of the PSRAM shown in FIG. 13; and

FIG. 17 is a timing chart showing a non-wrap burst operation of the PSRAM shown in FIG. 15.

### DETAILED DESCRIPTION OF THE INVENTION

The semiconductor memory according to the present invention comprises data I/O buses, a plurality of latch circuits, a memory cell array, sense amplifier activating means, a column decoder, and control means. The plurality of latch circuits are connected in common to the data I/O bus. The memory cell array includes a plurality of bit line pairs, a plurality of bit switches, a plurality of column selection lines, and a plurality of sense amplifiers. The plurality of bit switches are connected between the plurality of latch circuits and the plurality of bit line pairs and divided into a plurality of groups. The plurality of column selection lines are provided so as to correspond to the plurality of groups. Each column selection line is connected to a plurality of bit switches included in the corresponding group. The plurality of sense amplifiers are connected to the plurality of bit line pairs. The sense amplifier activating means activates the sense amplifiers. The column decoder drives the column selection lines. The control means controls the column decoder so as to drive two or more of the column selection lines in order during activation of the sense amplifiers.

The burst operation method according to the present invention comprises a sense amplifier activating step of activating the sense amplifiers and a column selection line driving step of driving two or more of the column selection lines in order during activation of the sense amplifiers.

According to the semiconductor memory and the burst operation method therefor, two or more column selection lines are driven in order during activation of the sense amplifiers. Upon a drive of a first column selection line, there are turned on a plurality of bit switches included in the group corresponding to the column selection line. When data is read, plural-bit read data is thereby prefetched into a latch circuit from a plurality of corresponding bit line pairs. Upon a subsequent drive of a second column selection line, there are turned on a plurality of bit switches included in another group corresponding to the column selection line. Thereby, further plural-bit read data is prefetched into a latch circuit. In other words, the data is continuously output in order in units of a single bit to a data I/O bus for which the read data is prefetched into a latch circuit in units of a plurality bits every time a column selection line is driven. Likewise, when data is written, plural-bit write data is preloaded into a latch circuit from the data I/O bus, and the write data is given to a bit line pair in units of a plurality of bits every time the column selection line is driven. Plural-bit read or write data is transferred more than once during activation of the sense amplifiers as mentioned above, thereby enabling an increase of the burst length without increasing consumed current.

Preferably the memory cell array is divided into a plurality of blocks. The above semiconductor memory further comprises block selection means for selecting a block. The sense amplifier activating means selectively activates sense amplifiers in the selected block.

Additionally, the above burst operation method further comprises a step of selecting a block. In the sense amplifier activating step, sense amplifiers are selectively activated in the selected block.

In this case, the sense amplifiers in the selected block are activated and the sense amplifiers in other blocks are not activated, thereby reducing current consumed by the sense amplifiers.

Preferably the semiconductor memory operates in synchronization with an external clock. The control means drives two or more column selection lines in order asynchronously with the external clock.

On the other hand, in the column selection line driving step, two or more column selection lines are driven in order asynchronously with the external clock.

Since the column selection lines are driven in order asynchronously with the external clock in this case, plural-bit read data can be prefetched quickly more than once and thereby read data can be continuously output without a gap on the data I/O bus in the non-wrap burst mode.

The preferred embodiments of the present invention will now be described in detail hereinafter with reference to the accompanying drawings. The same reference numerals have been retained for identical or equivalent parts in the drawings, and their descriptions are omitted hereinafter.

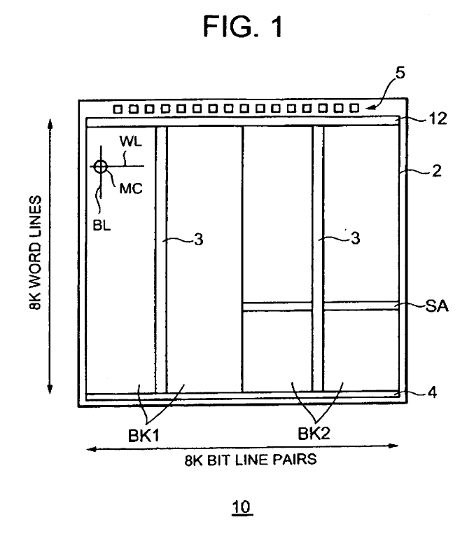

Referring to FIG. 1, there is shown a PSRAM 10 according to this embodiment of the present invention, which comprises a memory cell array 2 including memory cells MC of 64M, word lines WL of 8K, and bit line pairs BL of 8K. The memory cell array 2 is divided into array blocks BK1 and BK2.

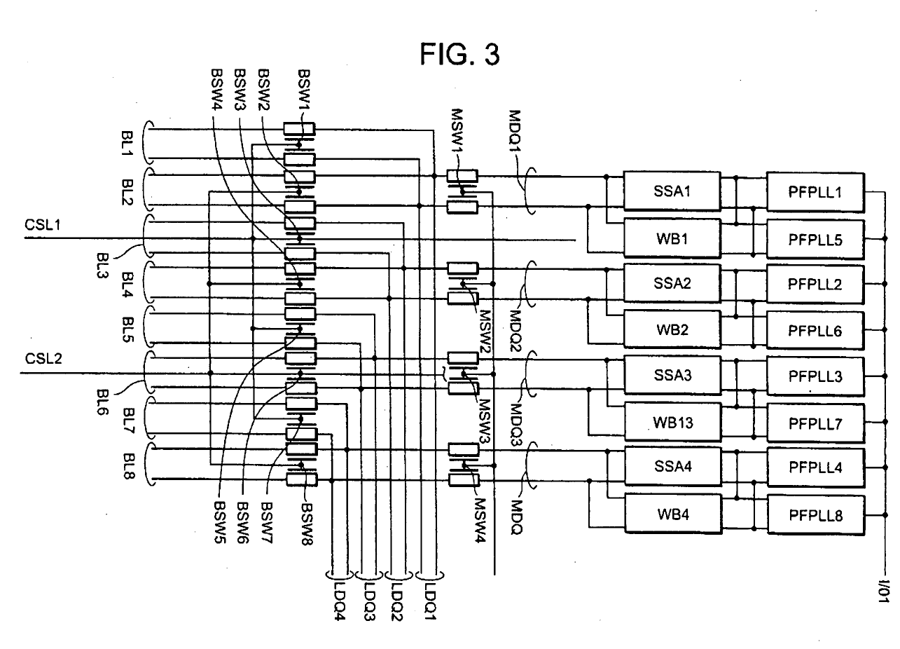

The PSRAM 10 further comprises row decoders 3 for selectively driving the word lines WL, a column decoder 4 for selecting the bit line pairs BL by driving the column selection lines (FIG. 3) running along the bit line pair BL, 16 data I/O buses 5, and a data path circuit 12 for exchanging read or write data between the memory cell array 2 and the data I/O buses. The column decoder 4 also has a function of selecting a selection array block BK1 or BK2.

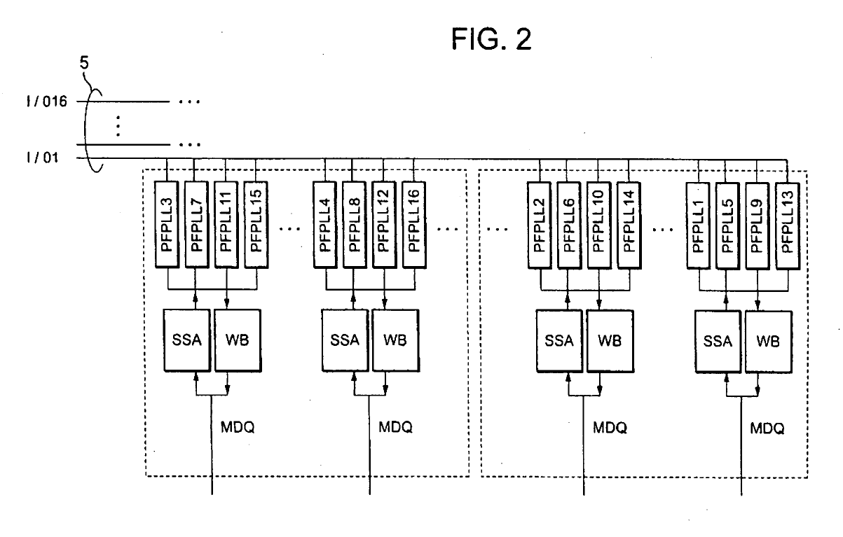

FIG. 2 illustrates a configuration of a half of the data path circuit 12 corresponding to a single array block BK1 or BK2. Referring to FIG. 2, there is shown the half of the data path circuit 12 including 64 secondary sense amplifiers SSA, 64 write buffers WB, and 256 prefetch/preload latches PFPLL. Therefore, the entire data path circuit 12 includes 128 secondary sense amplifiers SSA, 128 write buffers WB, and 512 prefetch/preload latches PFPLL.

Each secondary sense amplifier SSA supplies read data read from the memory cell array 2 to corresponding prefetch/preload latches PFPLL. Each write buffer WB supplies write data received from the data I/O bus 5 to corresponding prefetch/preload latches PFPLL. The prefetch/preload latches PFPLL temporarily retain the read or write data.

There are provided 16 prefetch/preload latches PFPLL for each data I/O bus 5 correspondingly. For example, 16 prefetch/preload latches PFPLL 1-16 are connected in common to a single data I/O bus I/O0.

FIG. 3 partially illustrates the memory cell array 2 and the data path circuit 12 in detail. Referring to FIG. 3, there are shown bit switches BSW1-BSW8 provided so as to correspond to bit line pairs BL1-BL8. The bit switches BSW1-BSW8 are connected between the bit line pairs BL1-BL8 and local I/O line pairs LDQ1-LDQ4.

Furthermore, a single column selection line is provided for four bit line pairs. Each column selection line is connected to four bit switches. Specifically, a column selection line CSL1 is connected to the bit switches BSW1, BSW3, BSW5, and BSW7, and a column selection line CSL2 is connected to the bit switches BSW2, BSW4, BSW6, and BSW8.

The column decoder 4 (FIG. 1) selectively drives the column selection lines CSL1 and CSL2 in response to a column address signal. If the column selection line CSL1 is selected, the bit switches BSW1, BSW3, BSW5, and BSW7 are turned on and then the bit line pairs BL1, BL3, BL5, and BL7 are connected to the local I/O line pairs LDQ1-LDQ4. If the column selection line CSL2 is selected, the bit switches BSW2, BSW4, BSW6, and BSW8 are turned on and then the bit line pairs BL2, BL4, BL6, and BL8 are connected to the local I/O line pairs LDQ1-LDQ4.

As stated above, the bit line pairs and the bit switches are divided into a plurality of groups. A plurality of column selection lines are provided so as to correspond to the plurality of groups. For example, the bit line pairs BL1, BL3, BL5, and BL7 and the bit switches BSW1, BSW3, BSW5, and BSW7 belong to a single group corresponding to the column selection line CSL1. The bit line pairs BL2, BL4, BL6, and BL8 and the bit switches BSW2, BSW4, BSW6, and BSW8 belong to another group corresponding to the column selection line CSL2.

In addition, main switches MSW1-MSW4 and main I/O line pairs MDQ1-MDQ4 are provided so as to correspond to local I/O line pairs LDQ1-LDQ4. The main switches MSW1 to MSW4 are connected between the local I/O line pairs LDQ1-LDQ4 and the main I/O line pairs MDQ1-MDQ4, respectively, and they are turned on or off simultaneously.

Furthermore, secondary sense amplifiers SSA and write buffers WB are provided so as to correspond to the main I/O line pairs MDQ1-MDQ4. Prefetch/preload latches PFPLL are further provided so as to correspond to the secondary sense amplifiers SSA and the write buffers WB. Each of the main I/O line pairs MDQ1-MDQ4 is connected to corresponding two prefetch/preload latches PFPLL via a corresponding secondary sense amplifier SSA. For example, the main I/O line pair MDQ1 is connected to the prefetch/preload latches PFPLL1 and PFPLL2 via the secondary amplifier SSA1. Additionally, each of the main I/O line pairs MDQ1-MDQ4 is connected to corresponding two prefetch/preload latches PFPLL via a corresponding write buffer WB. For example, the main I/O line pair MDQ1 is connected to the prefetch/preload latches PFPLL1 and PFPLL2 via the write buffer WB1.

The prefetch/preload latches PFPLL1-PFPLL8 are connected to a single data I/O bus I/O1.

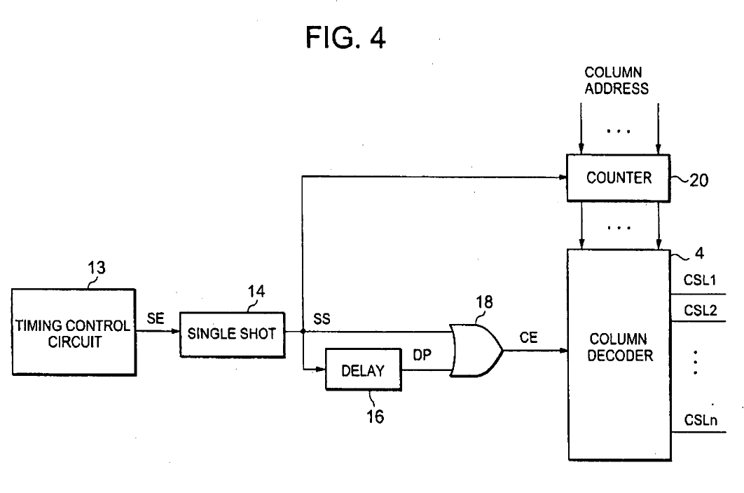

FIG. 4 illustrates the column decoder 4 and its peripheral circuits. Referring to FIG. 4, there is shown the PSRAM 10 further comprising a timing control circuit 13, a single-shot circuit 14, a delay circuit 16, an OR circuit 18, and a counter 20.

The timing control circuit 13 generates various timing control signals besides a sense amplifier enable signal SE for activating the sense amplifiers SA. The single-shot circuit 14 generates a single-shot pulse SS in response to the sense amplifier enable signal SE. The delay circuit 16 outputs a delay pulse DP, imposing a delay by a given period of time in the single-shot pulse SS. The OR circuit 18 outputs a logical add of the single-shot pulse SS and the delay pulse DP as a column enable signal CE. The counter 20 retains a column address and increments the retained column address at a trailing edge of the single-shot pulse SS. The column decoder 4 is activated in response to the column enable signal CE and drives column selection lines CSL1-CSLn in response to a column address given by the counter 20.

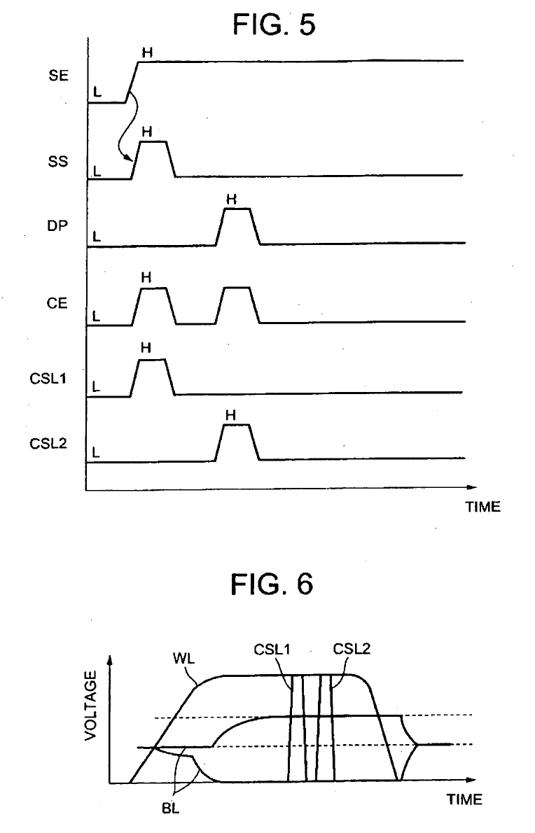

With reference to FIG. 5, the single-shot circuit 14 generates a single-shot pulse SS when the sense amplifier enable signal SE is activated to an H (logical high) level. The single-shot pulse SS is delayed by a given period of time by the delay circuit 16, which causes a delay pulse DP to be generated. The single-shot pulse SS and the delay pulse DP are supplied to the OR circuit 18, by which a column enable signal CE including two pulses is generated.

First, upon the first pulse of the column enable signal CE, the decoder 4 is activated and a column selection line CSL1 is driven in response to the column address of the counter 20. Subsequently, the column address of the counter 20 is incremented in response to a trailing edge of the single-shot pulse. Then, upon the second pulse of the column enable signal CE, the decoder 4 is activated again and a column selection line CSL2 is driven in response to the incremented column address of the counter 20.

As stated above, two column selection lines CSL1, CSL2 are sequentially driven while the sense amplifiers SA are activated in response to the sense amplifier enable signal SE.

Below is a description of a burst read operation of the PSRAM 10.

(1) 8-Bit Burst with Two Shots and 4-Bit Prefetch

Referring to FIGS. 1-3 and FIG. 6, one (BK2 in FIG. 1) of the array blocks BK1 and BK2 is selected and data is read out to a 4K bit line pair BL upon a drive of a single word line WL according to a row access. The 4K sense amplifier SA connected to the 4K bit line pair BL is then activated and the read data is amplified.

In this mode, the column selection line CSL1 is driven, first. This causes the bit switches BSW1, BSW3, BSW5, and BSW7 to be turned on, by which 4-bit read data RD is transferred from the bit line pairs BL1, BL3, BL5, and BL7 to the local I/O line pairs LDQ1-LDQ4.

Subsequently, when the main switches MSW1-MSW4 are turned on, the 4-bit read data RD is further transferred from the local I/O line pairs LDQ1-LDQ4 to the main I/O line pairs MDQ1-MDQ4.

Therefore, the 4-bit read data RD is amplified by the secondary sense amplifiers SSA1-SSA4 and latched into the prefetch/preload latches PFPLL1-PFPLL4.

When driving the column selection line CSL1 as stated above, the 4-bit read data RD is prefetched from the bit line pairs BL1, BL3, BL5, and BL7 to the prefetch/preload latches PFPLL1-PFPLL4. A drive of a column selection line or an ON operation of bit switches caused thereby is hereinafter referred to as “shot.”

The column selection line CSL2 is driven continuously in this mode. This causes the bit switches BSW2, BSW4, BSW6, and BSW8 to be turned on, by which the 4-bit read data. RD is transferred from the bit line pairs BL2, BL4, BL6, and BL8 to the local I/O line pairs LDQ1-LDQ4.

Subsequently, when the main switches MSW1-MSW4 are turned on, the 4-bit read data RD is transferred to the main I/O line pairs MDQ1-MDQ4 similarly to the above and is amplified by the secondary sense amplifiers SSA1-SSA4. It is, however, latched into the prefetch/preload latches PFPLL5-PFPLL8, unlike with the above.

Upon a drive of the column selection line CSL2 in this manner, the 4-bit read data RD is prefetched from the bit line pairs BL2, BL4, BL6, and BL8 to the prefetch/preload latches PFPLL5-PFPLL8.

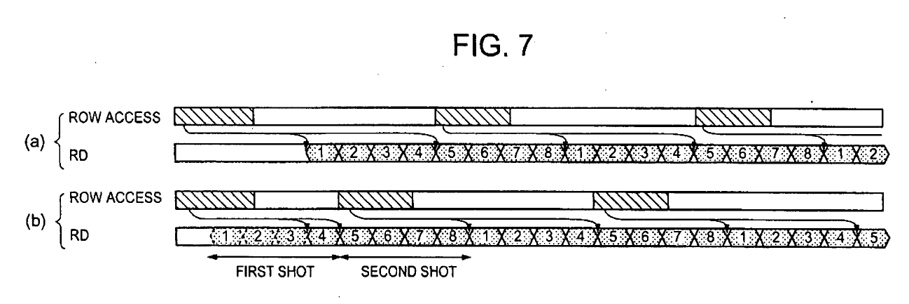

As a result of the two prefetch operations of the read data RD in units of 4 bits with two shots for a single row access as stated above, 8-bit read data RD is latched into eight prefetch/preload latches PFPLL1-PFPLL8. The 8-bit read data RD is output to the corresponding single data I/O bus I/O1 in units of a bit in order in response to the external clock as shown in FIG. 7(a). The burst length in this case is 8 bits.

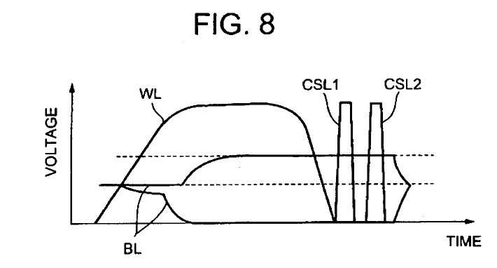

The column selection lines CSL1 and CSL2 are driven in order while the sense amplifiers are active and the word lines WL are in the driven state in the above example as shown in FIG. 6. There is no need, however, for driven word lines WL to be in the driven state when the column selection lines CSL1 and CSL2 are driven, but only the activated sense amplifiers are required as shown in FIG. 8. In other words, it is also possible to drive the column selection lines CSL1, CSL2 in order before deactivating the sense amplifiers while maintaining the activation of the sense amplifiers for a given period of time after the trailing edge of the word lines WL.

(2) 16-Bit Burst with Two Shots, 4-Bit Prefetch, and Two Row Accesses

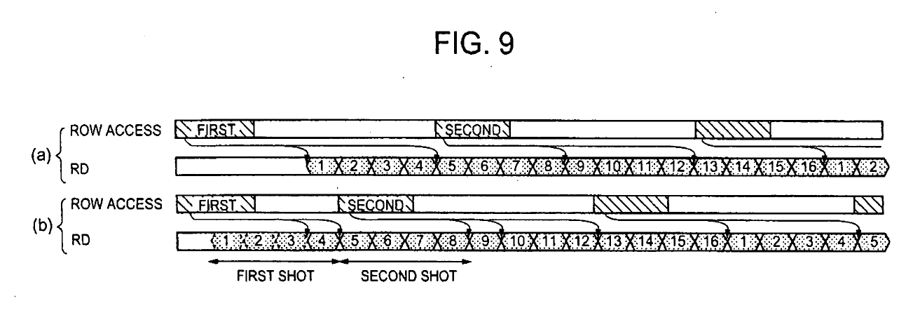

While 8-bit burst read data RD is output by a single row access in the above operation in item (1), it is also possible to output burst read data RD of 16 bits in total by two row accesses as shown in FIG. 9(a).

An operation to the first row access is the same as in the above: 8-bit read data RD is latched into eight prefetch/preload latches PFPLL1-PFPLL8.

Subsequently, upon the second row access, 8-bit read data RD is latched into eight prefetch/preload latches PFPLL9-PFPLL16.

Specifically, 4-bit read data RD is prefetched at the first shot and latched into four prefetch/preload latches PFPLL9-PFPLL12. Then, 4-bit read data RD is prefetched at the second shot and latched into four prefetch/preload latches PFPLL13-PFPLL16.

The 16-bit read data RD is latched into the 16 prefetch/preload latches PFPLL1-PFPLL16 by two row accesses in this manner and is output to the corresponding single data I/O bus I/O1 in units of a bit in order in response to the external clock.

(3) 16 Bit Burst with Four Shots and 4-Bit Prefetch

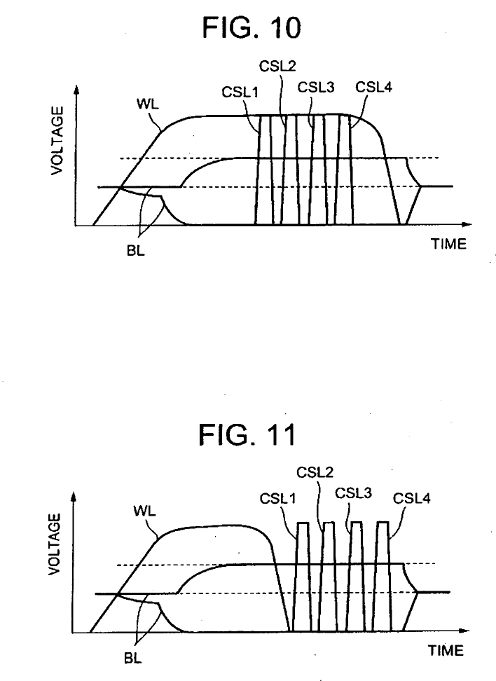

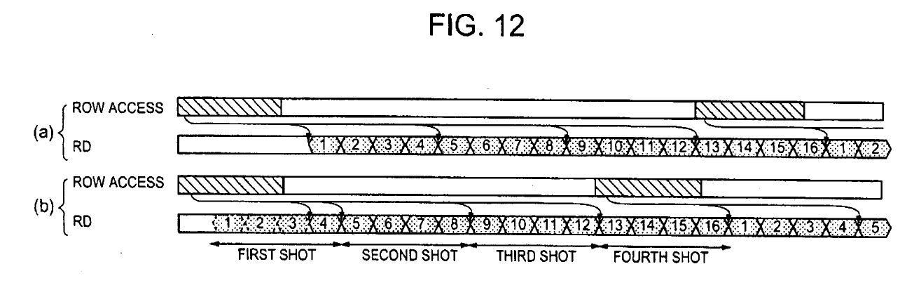

While the two column selection lines CSL1, CLS2 are driven in order as shown in FIG. 6 and FIG. 8 in the operations of the above (1) and (2), four column selection lines CSL1-CSL4 can be driven in order as shown in FIG. 10 and FIG. 11. In this case, 16-bit burst read data RD is output by a single row access as shown in FIG. 12(a).

Specifically, 4-bit read data RD1-RD4 is prefetched at the first shot and latched into four prefetch/preload latches PFPLL1-PFPLL4. Then, 4-bit read data RD5-RD8 is prefetched at the second shot and latched into four prefetch/preload latches PFPLL5-PFPLL8. Thereafter, 4-bit read data RD9-RD12 is prefetched at the third shot and latched into four prefetch/preload latches PFPLL9-PFPLL12. Then, 4-bit read data RD13-RD16 is prefetched at the fourth shot and latched into four prefetch/preload latches PFPLL13-PFPLL16.

In this manner, 16-bit read data RD1-RD16 is latched into 16 prefetch/preload latches PFPLL1-PFPLL16 by a single row access and then output to the corresponding single data I/O bus I/O1 in units of a bit in order in response to the external clock.

As apparent from the above, the number of column selection lines to be driven in order only needs to be two or more. If four column selection lines CSL1-CSL4 are driven in order for a 4-bit prefetch length as described in this embodiment, a burst length becomes 16 bits. In general, the burst length=the prefetch length×the number of shots.

(4) Non-Wrap Burst

The above burst operations, (1), (2), and (3) are performed for a case where the first column address to be accessed is coincident with the first column address of the burst area. The following describes an operation for a case where the first column address to be accessed coincides with the last column address of the prefetch area.

As shown in FIG. 7(b), FIG. 9(b), and FIG. 12(b), 4-bit read data RD1-RD4 is prefetched at the first shot and the subsequent 4-bit read data RD5-RD8 is prefetched at the next shot in every case.

The shots are asynchronous with the external clock and controlled by internal timing circuits 14, 16, and 18 shown in FIG. 4. Therefore, the time period between the shots can be reduced to a half or so of the external clock period. Thereby, read data RD can be continuously output without a gap in the non-wrap burst mode, too. Furthermore, it is also possible to make continuous accesses exceeding prefetch areas.

In addition, an array operation cycle time is much shorter than an 8-bit burst time, and therefore a time period between row accesses is at least twice as long as the array operation cycle time. There is enough time to insert a refresh during the time period, thereby satisfying a request to the PSRAM for an internal automatic refresh function.

While the embodiment has been described by giving an example of the read operation in the above, the write operation is basically the same as described above.

In addition, while it has been described with the 8- or 16-bit burst length, the burst length can be, for example, 32 or 64 bits. In other words, any burst length can be used as far as the length of the word line WL permits. Therefore, an extremely long burst length is achieved without increasing a prefetch length. Furthermore, the long burst operation is achieved without a gap.

In this manner, a burst length to a full page is achieved at low power consumption with a short prefetch length of 4 bits by performing the basic operation with the two shots and 4-bit prefetch.

The SDRAM full-page burst mode is achieved by accessing a column address with a plurality of activated 8K sense amplifiers. In the PSRAM, however, there is no timing for automatically inserting a refresh and therefore this operation mode is not permitted.

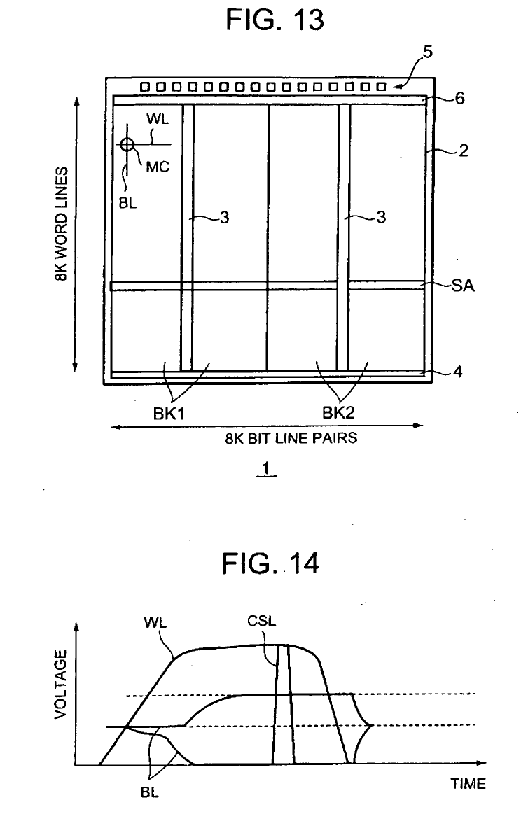

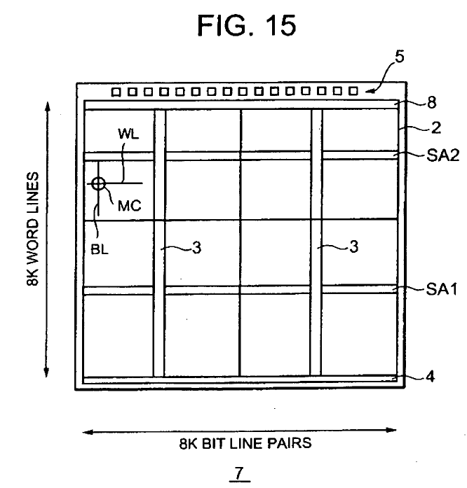

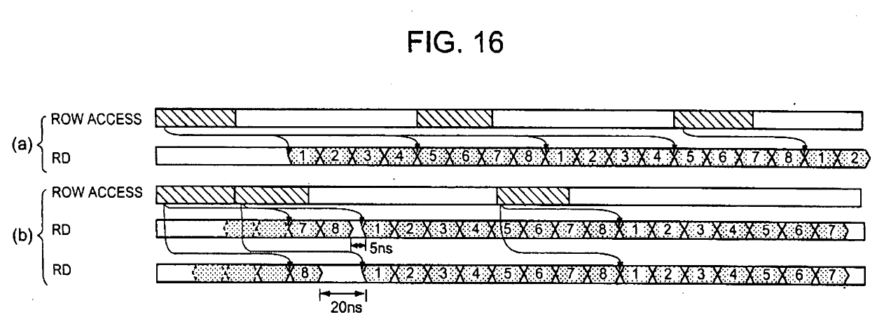

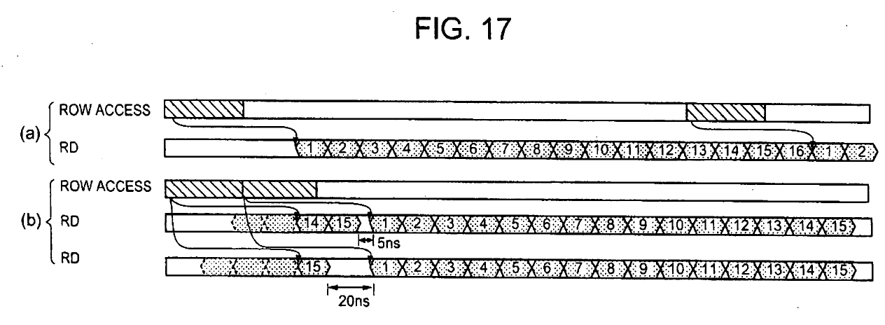

According to this embodiment, a prefetch length for each input or output is always 4-bits independently of a burst length as stated above. To achieve an 8-bit burst length, it has conventionally been necessary to activate sense amplifiers SA1 of 8K as shown in FIG. 13. In this embodiment, however, it is only necessary to activate sense amplifiers SA of 4K as shown in FIG. 1. Since the sense amplifiers to be activated are reduced by half in this manner, the current flowing in memory cell array 2 is also reduced by half.

Likewise, the same operation as for the SDRAM is enabled with a 4-bit short prefetch and a row access is repeated during an array operation cycle time much shorter than the 8-bit burst length in this embodiment. Therefore, enough time is secured for inserting a refresh, thereby satisfying an internal automatic refresh function required for the PSRAM.

While the embodiment of the present invention has been described hereinabove, it is only illustrated in order to put the invention into practice. Therefore, it is to be understood that the subject matter encompassed by the present invention is not limited to the specific embodiment. On the contrary, it is intended to include appropriate alternatives or modifications of the embodiment as can be included within the spirit and scope of the claims.

The semiconductor memory according to the present invention is applicable particularly to a DRAM (PSRAM) capable of inserting a refresh operation during a normal access operation.

What is claimed is:

1. A semiconductor memory, comprising:
data I/O buses;
a plurality of latch circuits connected in common to each of said data I/O buses;
a memory cell array including a plurality of bit line pairs, a plurality of bit switches connected between said plurality of latch circuits and said plurality of bit line pairs and divided into a plurality of groups, a plurality of column selection lines provided so as to correspond to said plurality of groups and each of which is connected to a plurality of bit switches included in the corresponding group, and a plurality of sense amplifiers connected to said plurality of bit line pairs;
activating said sense amplifiers using an sense amplifier enable signal;
a column decoder for driving said column selection lines; and
a control enable signal which controls the column decoder so as to drive two or more of said column selection lines in order during activation of said sense amplifiers.

2. The memory according to claim 1, wherein said memory cell array is divided into a plurality of blocks; said semiconductor memory further comprises a block selection signal for selecting said block; and
said sense amplifier enable signal activates said sense amplifiers in said selected block.

3. The memory according to claim 1, wherein said semiconductor memory operates in synchronization with an external clock; and
said control enable signal drives said two or more of said column selection lines in order asynchronously with the external clock.

4. A burst operation method for a semiconductor memory having data I/O buses, a plurality of latch circuits connected in common to each of said data I/O buses, and a memory cell array, in which said memory cell array includes a plurality of bit line pairs, a plurality of bit switches connected between said plurality of latch circuits and said plurality of bit line pairs and divided into a plurality of groups, a plurality of column selection lines provided so as to correspond to said plurality of groups and each of which is connected to a plurality of bit switches included in the corresponding group, and a plurality of sense amplifiers connected to said plurality of bit line pairs, the burst operation method, comprising the steps of:
activating said sense amplifiers; and
driving two or more of said column selection lines in order during activation of said sense amplifiers.

5. The method according to claim 4, wherein said memory cell array is divided into a plurality of blocks; said burst operation method further comprises a step of selecting said block; and
the sense amplifiers in the selected block are selectively activated in said sense amplifier activating step.

6. The method according to claim 4, wherein said semiconductor memory operates in synchronization with an external clock; and
said two or more of the column selection lines are driven in order synchronously with the external clock in said column selection line driving step.
